(19) United States
(12) Patent Application Publication
(10) Pub. No.: US 2017/0162818 A1
(43) Pub. Date: Jun. 8, 2017

(54) DISPLAY DEVICE, DISPLAY UNIT, AND ELECTRONIC APPARATUS

(71) Applicant: JOLED Inc., Tokyo (JP)

(72) Inventor: Yasunori Kijima, Tokyo (JP)

(21) Appl. No.: 15/439,675

(22) Filed: Feb. 22, 2017

Related U.S. Application Data
(63) Continuation of application No. PCT/JP2015/067145, filed on Jun. 15, 2015.

(30) Foreign Application Priority Data
Sep. 4, 2014 (JP) 2014-180058
Dec. 9, 2014 (JP) 2014-248979

(51) Int. Cl. H01L 51/50; H01L 51/52

(52) U.S. Cl. CPC H01L 51/5072; H01L 51/5012; H01L 51/5206; H01L 51/5221

(57) ABSTRACT

A display device includes a first electrode, a second electrode, a light-emitting layer, and an organic material layer. The light-emitting layer is included in an organic layer. The organic layer is provided between the first electrode and the second electrode. The organic material layer is provided between the first electrode and the light-emitting layer, and has microcrystallinity.

### CROSS REFERENCE TO RELATED APPLICATIONS

This is a continuation of International Application No. PCT/JP2015/067145, filed Jun. 15, 2015, which claims the benefit of Japanese Priority Patent Application JP2014-180058, filed Sep. 4, 2014, and Japanese Priority Patent Application JP2014-248979, filed Dec. 9, 2014 the entire contents of all of which are incorporated herein by reference.

### BACKGROUND

The disclosure relates to a display device that emits light utilizing an organic electro luminescence (EL) phenomenon, a display unit including the display device, and an electronic apparatus.

Recently, along with the spread of smartphones and pad display media, for example, an interface between a person and a machine has become increasingly important. In order for a person to operate a machine more comfortably and efficiently, it is desirable to extract a sufficient amount of information briefly and instantly without any error from a machine that is operated. Thus, development for various display devices has been conducted.

An organic electroluminescence display devices has attracted attention as a major candidate of a next-generation display device; however, the efficiency of extracting light emitted from a light-emitting layer to the outside has been as low as about 20% to 30%. Therefore, improvements in the light extraction efficiency have been tried to be achieved, for example, by forming a reflector structure inside the display device, or by adding a member such as a diffraction grating film, a micro lens array and an optical prism, as illustrated, for example, in Japanese Unexamined Patent Application Publications No. 2008-204948, No. 2006-335881, No. 2009-217292, and No. 2010-103120.

### SUMMARY

However, formation of a structure inside a display device causes increased manufacturing steps, which leads to complicated manufacturing steps. Further, addition of a lens component such as a micro lens array causes expression of a diffraction pattern due to presence of a cycle pattern or a large influence on scattered light. Thus, the display device with the lens component being added may be used for applications such as illumination, but is not suitable for a display that involves address display, which causes the application range thereof to electronic apparatuses to be limited. Further, increased number of components also causes increased cost.

It is desirable to provide a display device that makes it possible to improve light extraction efficiency with a simple method, a display unit using the display device, and an electronic apparatus.

A display device according to an embodiment of the technology includes a first electrode, a second electrode, a light-emitting layer, and an organic material layer. The light-emitting layer is included in an organic layer. The organic layer is provided between the first electrode and the second electrode. The organic material layer is provided between the first electrode and the light-emitting layer, and has microcrystallinity.

A display unit according to an embodiment of the technology includes a plurality of display devices. Each of the display devices includes a first electrode, a second electrode, a light-emitting layer, and an organic material layer. The light-emitting layer is included in an organic layer. The organic layer is provided between the first electrode and the second electrode. The organic material layer is provided between the first electrode and the light-emitting layer, and has microcrystallinity.

An electronic apparatus according to an embodiment of the technology is provided with the display unit as a display section. The display unit includes a plurality of display devices. Each of the display devices includes a first electrode, a second electrode, a light-emitting layer, and an organic material layer. The light-emitting layer is included in an organic layer. The organic layer is provided between the first electrode and the second electrode. The organic material layer is provided between the first electrode and the light-emitting layer, and has microcrystallinity.

### BRIEF DESCRIPTION OF THE DRAWINGS

FIG. 1 is a cross-sectional view of a display device according to an embodiment of the disclosure.

FIG. 2 is a plan view of a configuration of a display unit including the display device illustrated in FIG. 1.

FIG. 3 illustrates an example of a pixel drive circuit of the display unit illustrated in FIG. 2.

FIG. 4 illustrates an example of cross-sectional configuration of the display unit illustrated in FIG. 2.

FIG. 5 is a cross-sectional view of a display device according to a modification example of the disclosure.

FIG. 6 is a plan view of a schematic configuration of a module including the display unit.

FIG. 7 is a perspective view of an outer appearance of Application Example 1 of the display unit.

FIG. 8A is a perspective view of an outer appearance of Application Example 2 of the display unit as viewed from front side.

FIG. 8B is a perspective view of an outer appearance of Application Example 2 illustrated in FIG. 8A as viewed from rear side.

FIG. 9 is a perspective view of an outer appearance of Application Example 3 of the display unit.

FIG. 10 is a perspective view of an outer appearance of Application Example 4 of the display unit.

FIG. 11A is a perspective view of an outer appearance of Application Example 5 of the display unit as viewed from front side.

FIG. 11B is a perspective view of an outer appearance of Application Example 5 illustrated in FIG. 11A as viewed from rear side.

FIG. 12 illustrates measurement results of surface roughness in Example 4.

FIG. 13 is a characteristic diagram illustrating dependency of luminance on viewing angle in Examples and Comparative Examples.

### DETAILED DESCRIPTION

Some example embodiments of the disclosure are described in detail, in the following order, with reference to the accompanying drawings.

1. First Embodiment (An example in which an electron transport layer has a layered structure, with one layer being made of a microcrystalline organic material)

1-1. Configuration of Display Device

1-2. Configuration of Display Unit

2. Modification Example (An example in which electron transport layers each made of a microcrystalline organic material are stacked)

### 3. Application Examples

### 4. Examples

### 1. EMBODIMENT

### (1-1. Configuration of Display Device)

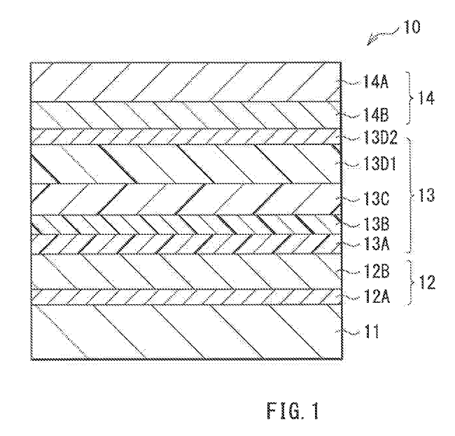

FIG. 1 illustrates a cross-sectional configuration of a display device (display device 10) according to an embodiment of the disclosure. The display device 10 may have a configuration in which an anode 12 (second electrode), an organic layer 13 including a light-emitting layer 13C, and a cathode 14 (first electrode) are stacked in this order on a substrate 11. The organic layer 13 may have a configuration in which, for example, a hole injection layer 13A and a hole transport layer 13B as hole supply layers, a light-emitting layer 13C, and electron transport layer 13D as an electron supply layer are stacked in order from anode 12 side. It is to be noted that each of the components may either has a monolayer structure or a layered structure. In a typical display device, each component made of an organic material may be formed of a non-crystalline (amorphous) material in order to secure in-plane uniformity of electric field intensity. In contrast, in the present embodiment, the electron transport layer 13D (organic material layer), out of the organic layer 13, may have a multi-layered structure (two-layer structure in this example); one layer of the electron transport layer 13D may be formed of a microcrystalline organic material.

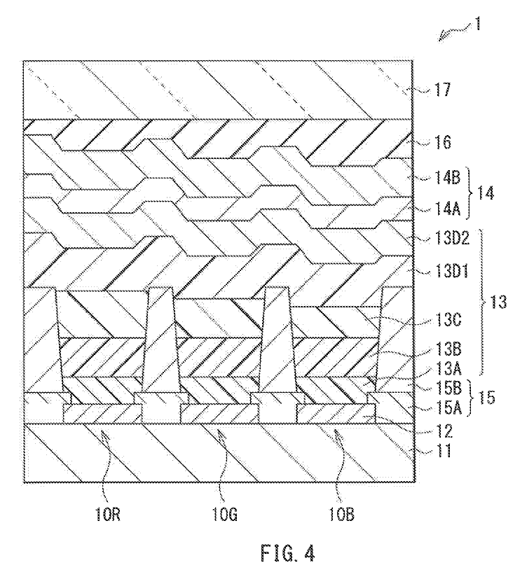

The display device 10 may be a top surface emission (top emission) display device that extracts, from a substrate (sealing substrate 17, see FIG. 4) on cathode 14 side, emission light generated during recombination, inside the light-emitting layer 13C, of holes injected from the anode 12 and electrons injected from the cathode 14. It is to be noted that the display device according to the embodiment of the disclosure is not limited to the top emission display device, and may be a bottom surface emission (bottom emission) display device that extracts light from substrate 11 side, for example.

The substrate 11 may be a support having a main surface on which a plurality of display devices 10 are arranged and provided. A known material such as quartz, glass, metal foil, and a film or sheet made of resin may be used as the substrate 11. Among those, quartz and glass may be preferable. In the case of using the film or sheet made of resin, examples of the resin material may include methacrylic resins typified by polymethylmethacrylate (PMMA); polyesters such as polyethylene terephthalate (PET), polyethylene naphthalate (PEN), and polybutylene naphthalate (PBN); and a polycarbonate resin. It is desirable for the resin to have a layered structure that suppresses moisture permeability and gas permeability and to be subjected to a surface treatment.

The anode 12 may be provided for injecting holes into the organic layer 13, and may be made of a material having a large work function from a vacuum level. Specific examples of the material may include a metal simple substance such as chromium (Cr), gold (Au), platinum (Pt), nickel (Ni), copper (Cu), tungsten (W), and silver (Ag), and an alloy thereof. Further, the anode 12 may have a layered structure of a metal film and a transparent electrically conductive film. The metal film may be made of a metal simple substance or an alloy thereof. Examples of the transparent electrically conductive film may include indium tin oxide (ITO), indium zinc oxide (InZnO), and an alloy of zinc oxide (ZnO) and aluminum (Al). The thickness in a layered direction (hereinafter, referred to simply as “thickness”) of the anode 12 may be preferably 10 nm or more and 3,000 nm or less.

In the case of the top emission display device 10, in particular, use of an electrode material having high reflectivity for the anode 12 may allow for improved efficiency of extracting light to the outside owning to an interference effect and a high reflectivity effect. Therefore, it is preferable that the anode 12 may have a layered structure of a layer (first layer 12A) excellent in light reflectivity and a second layer (second layer 12B) having light-transmissivity, for example.

For example, for the first layer 12A, it is preferable to use an alloy having a main component of Al; as a sub-component, an element having a relatively smaller work function than that of Al as the main component may be used. As the sub-component, for example, a lanthanide element may be used. Although the lanthanide element does not have a large work function, the element contained in the first layer 12A enhances the stability of the anode, and also satisfies the hole-injection property of the anode. Further, elements such as silicon (Si) and copper (Cu), in addition to the lanthanide element, may also be used as the sub-component.

As the second layer 12B, an Al alloy oxide, molybdenum (Mo) oxide, zirconium (Zr) oxide, Cr oxide, or tantalum (Ta) oxide may be used. For example, when the second layer 12B is a layer of the Al alloy oxide (including a naturally oxidized layer) containing the lanthanide element as the sub-component, the second layer 12B containing the lanthanide element oxide is favorable because of the high transmissivity thereof. This allows the reflectivity on the surface of the first layer 12A to be kept high. Further, use of the transparent electrically conductive layer such as ITO and IZO for the second layer 12B may improve a hole injection property of the anode 12. It is to be noted that, because of a large work function of ITO and IZO, the use of ITO and IZO for the first layer 12A, i.e., as side in contact with the substrate 11 makes it possible to enhance carrier injection efficiency and to improve adhesion between the anode 12 and the substrate 11.

It is to be noted that, when a display unit 1 configured by the display device 10 is driven by an active matrix system, the anode 12 may be patterned for each pixel, and may be provided in a state coupled to an unillustrated driving thin film transistor (TFT) provided in the substrate 11. In this case, a partition wall (see FIG. 4) 15 may be provided on the anode 12, in such a configuration that the surface of the anode 12 of each pixel may be exposed from the opening of the partition wall 15.

The organic layer 13 may have a configuration in which the hole injection layer 13A, the hole transport layer 13B, the light-emitting layer 13C, and the electron transport layer 13D having a multi-layered structure are stacked in order from the anode 12 side as described above. These organic layers 13 may be formed by, for example, a vacuum vapor deposition method or a spin coating method, although the detail is described later. The upper surface of the organic layer 13 may be covered with an intermediate electrode 14. Film thickness and constituent material, for example, of each of the layers that configure the organic layer 13 are not particularly limited; examples thereof are described below.

The hole injection layer 13A may be a buffer layer for enhancing the efficiency of injecting holes into the light-emitting layer 13C and for preventing a leak. The hole injection layer 13A may have a thickness of, for example, preferably 5 nm to 200 nm both inclusive, and more preferably 8 nm to 150 nm both inclusive. It is sufficient for the constituent material of the hole injection layer 13A to be selected appropriately in terms of relationships with materials of the adjacent layer and the electrode. Examples of the constituent material of the hole injection layer 13A may include polyaniline, polythiophene, polypyrrole, polyphenylene vinylene, polythienylene vinylene, poly quinoline, polyquinoxaline and a derivative thereof, an electrically conductive polymer such as a polymer including an aromatic amine structure in a main chain or a side chain, metal phthalocyanine (such as copper phthalocyanine), and carbon. Specific examples of the electrically conductive polymer may include oligoaniline and polydioxythiophene such as poly(3,4-ethylenedioxythiophene) (PEDOT).

The hole transport layer 13B may be provided for enhancing the efficiency of transporting holes into the light-emitting layer 13C. The hole transport layer 13B may have a thickness of, for example, preferably 5 nm to 200 nm both inclusive, and more preferably 8 nm to 150 nm both inclusive, although it depends on the overall configuration of the device. Examples of the available constituent material of the hole transport layers 13B may include a luminescent material soluble in an organic solvent, such as polyvinyl carbazole, polyfluorene, polyaniline, polysilane, or a derivative thereof, a polysiloxane derivative having an aromatic amine in a main chain or a side chain, polythiophene and a derivative thereof, polypyrrole, and tris(8-hydroxy quinolinato)aluminium (Alq₃).

In the light-emitting layer 13C, application of an electric field causes electrons and holes to be recombined, thus allowing light to be emitted. The light-emitting layer 13C may have a thickness of, for example, preferably 10 nm to 200 nm both inclusive, and more preferably 20 nm to 150 nm both inclusive, although it depends on the overall configuration of the device. Each of the light-emitting layers 13C may have a monolayer structure or a layered structure, and may be, for example, a white light-emitting display device in which a red light-emitting layer, a green light-emitting layer, and a blue light-emitting layer are stacked. It is to be noted that the emission color of each of the light-emitting layers is not limited to any of a red color, a green color, and a blue color, and may be an orange color, for example. It is also possible to configure the white light-emitting display device by stacking the orange light-emitting layer and the blue and green light-emitting layers.

It is sufficient to use a material corresponding to each emission color as the constituent material of the light-emitting layer 13C. Examples of the material may include a polyfluorene-based polymer derivative, a (poly) paraphenylene-vinylene derivative, a polyphenylene derivative, a polyvinyl carbazole derivative, a polythiopene derivative, a perylene-based dyestuff, a coumarin-based dyestuff, a rhodamine-based dyestuff, or the above-described polymer with an organic EL material doped thereinto. As the doping material, it is possible to use, for example, rubrene, perylene, 9,10-diphenylanthracene, tetraphenyl butadiene, nile red, and coumarine 6. It is to be noted that, as the constituent material of the light-emitting layer 13C, two or more of the above-described materials may be mixed to be used. In addition, the material is not limited to the above-described material of high molecular weight; a material of a low molecular weight may also be combined to be used. Examples of the low molecular material may include benzine, styrylamine, triphenylamine, porphyrin, triphenylene, azatriphenylene, tetracyanoquinodimethane, triazole, imidazole, oxadiazole, polyaryl alkane, phenylenediamine, arylamine, oxazole, anthracene, fluorenone, hydrazone, stilbene, or a derivative thereof, and a monomer or an oligomer of a heterocyclic conjugated system such as a polysilane-based compound, a vinyl carbazole-based compound, a thiophene-based compound, and an aniline-based compound.

As the constituent material of the light-emitting layer 13C, it is possible to use, in addition to the above-described materials, a material with high luminous efficiency as a light emitting guest material, for example, an organic luminescent material such as a low molecular fluorescent material, a phosphorescence dyestuff, and a metal complex.

It is to be noted that the light-emitting layer 13C may be, for example, either a hole-transporting light-emitting layer that also serves as the above-described hole transport layer 13B, or an electron-transporting light-emitting layer that also serves as the electron transport layer 13D described later.

The electron transport layer 13D may be provided for enhancing the efficiency of transporting electrons into the light-emitting layer 13C, and may be configured by a two-layered structure of an electron transport layer 13D1 and an electron transport layer 13D2 as illustrated in FIG. 4. The electron transport layer 13D1 may have a thickness of, for example, preferably 5 nm to 200 nm both inclusive, and more preferably 10 nm to 180 nm both inclusive, although it depends on the overall configuration of the device.

As the material of the electron transport layer 13D1, it is preferable to use an organic material with an excellent electron transport capability. Specifically, it is preferable to use an arylpyridine derivative and a benzimidazole derivative, for example. Increasing transport efficiency of the light-emitting layer 13C makes it is possible to suppress a change in an emission color due to field intensity described later. This allows high electron supply efficiency to be maintained even in a low drive voltage. Other examples of the material of the electron transport layer 13D1 may include alkali metal, alkali earth metal, rare earth metal and an oxide thereof, a complex oxide, a fluoride, and a carbonate.

The electron transport layer 13D2 may have an electron transport property, and may be made of, for example, an organic material having single microcrystallinity (microcrystalline electron transport material). The microcrystalline electron transport material may preferably have an electron transport property that is similar to or higher than that of the material forming the electron transport layer 13D1. This makes it possible to improve light extraction efficiency and to maintain a property of injecting electrons into the electron transport layer 13D1. The electron transport layer 13D2 may have a thickness of, for example, preferably 1 nm to 100 nm both inclusive, and more preferably 10 nm to 50 nm both inclusive, although it depends on the overall configuration of the device.

The material of the electron transport layer 13D2 may preferably have a crystalline state of, for example, needle crystallinity or disk-shaped crystallinity; in particular, by using a material having the needle crystallinity that is oriented horizontally and randomly in an in-plane direction, it becomes possible to remarkably improve the light extraction efficiency. Examples of the material that is likely to be in such a microcrystalline state may include, but not limited to, a triphenylene derivative, an azatriphenylene derivative, a phthalocyanine derivative, an arylpyridine derivative, and a benzimidazol derivative. Further, the needle crystal may preferably have a crystal length of 1 (one) μm or less.

The cathode 14 may have a two-layered structure of a first layer 14A having transmissivity and a second layer 14B having relatively high refractive index than that of the first layer, similarly to the anode 12 described above. The cathode 14 may have a configuration in which the second layer 14B and the first layer 14A are stacked in order from side of an efficiency improvement layer 15. The cathode 14 may preferably have a total thickness of 30 nm or more and 2,500 nm or less; the first layer 14A may preferably have a thickness of 5 nm or more and 30 nm or less; and the second layer 14B may preferably have a thickness of 100 nm or more and 2,000 nm or less. The configurations of the first layer 14A and the second layer 14B may have similar configurations of the first layer 12A and the second layer 12B of the above-described anode 12, respectively, and the above-mentioned materials may be used appropriately for the first layer 14A and the second layer 14B.

### (1-2. Display Unit)

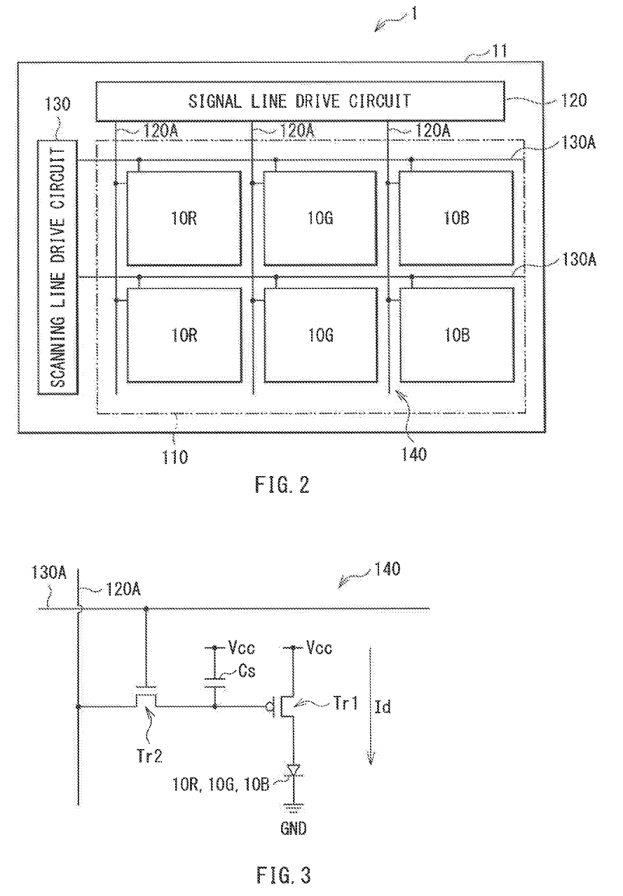

FIG. 2 illustrates a configuration of the display unit 1 including the display device 10 of the present embodiment. The display unit 1 may be used as an organic EL television or any other apparatus, and may have a configuration in which, for example, a plurality of display devices 10 (e.g., a red light-emitting display device 10R, a green light-emitting display device 10G, and a blue light-emitting display device 10B) are disposed in matrix, as a display region 110, on the substrate 11. On the periphery of the display region 110, there may be provided a signal line drive circuit 120 and a scanning line drive circuit 130 which are drivers for image display. It is to be noted that a combination of adjacent display devices 10 configure one pixel.

A pixel drive circuit 140 may be provided inside the display region 110. FIG. 3 illustrates an example of the pixel drive circuit 140. The pixel drive circuit 140 may be an active drive circuit provided below the anode 12. That is, the pixel drive circuit 140 may include a drive transistor Tr1, a write transistor Tr2, a capacitor (holding capacitor) Cs located between these transistors Tr1 and Tr2, and the display device 10 (e.g., 10R, 10G, and 10B) coupled in series to the drive transistor Tr1 between a first power supply line (Vcc) and a second power supply line (GND). Each of the drive transistor Tr1 and the write transistor Tr2 may be configured by a typical thin film transistor (TFT), and may have either an inverted staggered structure (a so-called bottom gate type) or a staggered structure (a top gate type); the configuration thereof is not particularly limited.

In the pixel drive circuit 140, a plurality of signal lines 120A may be arranged in a column direction, and a plurality of scanning lines 130A may be arranged in a row direction. An intersection of each of the signal lines 120A and each of the scanning lines 130A may correspond to one (sub-pixel) of the respective display devices 10. Each of the signal lines 120A may be coupled to the signal line drive circuit 120, and an image signal may be supplied from the signal line drive circuit 120 to source electrodes of the respective write transistors Tr2 through the signal lines 120A. Each of the scanning lines 130A may be coupled to the scanning line drive circuit 130, and a scanning signal may be sequentially supplied from the scanning line drive circuit 130 to gate electrodes of the respective write transistors Tr2 through the scanning lines 130A.

FIG. 4 illustrates a cross-sectional configuration of the display region 110 illustrated in FIG. 2. Each display device 10 may have a configuration in which the anode 12, the organic layer 13 including the light-emitting layer 13C, and the cathode 14 are stacked in this order from the substrate 11 side, with the drive transistor Tr1 and an unillustrated flattening insulating film of the pixel drive circuit 140 being provided between the substrate 11 and the anode 12, as described above. The respective display devices 10 may be partitioned by the partition wall 15. Further, the display devices 10 are covered with a protective layer 16. Further, the sealing substrate 17 such as glass may be joined onto the entire surface of the protective layer 16 with an unillustrated bonding layer such as a thermosetting resin or an ultraviolet-curable resin being interposed therebetween for sealing the display devices 10. As the protective layer 16, for example, a silicon nitride (typified by Si₃N₄) film, a silicon oxide (typified by SiO₂) film, a silicon nitride oxide (SiNₓO_{y}:composition ratio X>Y) film, a silicon oxynitride (SiOₓN_{y}:composition ratio X>Y) film, a thin film having carbon as a main component such as diamond-like carbon (DLC), or a carbon nanotube (CNT) film may be used. These films may preferably have a monolayer configuration or a layered configuration. In particular, a protective layer made of a nitride may have a dense film property, and may have an extremely high blocking effect against moisture, oxygen, and other impurities that have adverse influence on the display device 10.

The partition wall 15 may be provided for securing an insulating property between the anode 12 and the cathode 14 and for allowing an emission region to have a desired shape. The partition wall 15 may also have a function as a partition wall when forming the organic layer 13 by application methods such as an inkjet method and a nozzle coating method. The partition wall 15 may include a lower partition wall 15A and an upper partition wall 15B, for example. The lower partition wall 15A may be made of an inorganic insulating material such as SiO₂. The upper partition wall 15B may be provided on the lower partition wall 15A, and may be made of a photosensitive resin such as positive photosensitive polybenzoxazole and positive photosensitive polyimide. The partition wall 15 may have an opening provided to correspond to the emission region. It is to be noted that layers from the organic layer 13 to the cathode 14 may be provided not only in the opening but also on the partition wall 15, although light emission may occur only in the opening of the partition wall 15.

The protective layer 16 may have a thickness of, for example, 1 (one) μm to 3 μm both inclusive, and may be made of any of an insulating material or an electrically conductive material. Examples of the insulating material may include an inorganic amorphous insulating material such as amorphous silicon (α-Si), amorphous silicon carbide (α-SiC), amorphous silicon nitride (α-Si₁₋ₓNₓ), amorphous carbon (α-C), indium tin oxide (ITO), indium zinc oxide (InZnO), and indium titanium zinc oxide (ITZO). Such an inorganic amorphous insulating material does not form a grain, and thus the material has low moisture permeability, allowing the material to be a favorable protective film. The inorganic amorphous insulating material may sometimes exhibit microcrystallinity depending on film-forming conditions; however, it may be preferable that there is less occurrence of, for example, a scatter component that has an influence on optical light extraction. Thus, the inorganic amorphous insulating material may be appropriately selected in view of film thickness of a formed film, tack time, or productivity.

The sealing substrate 17 may be located on the cathode 14 side of the display device 10, and may seal the display device 10 together with an unillustrated bonding layer. The sealing substrate 17 may be made of a material such as glass transparent to light generated in the display device 10. The sealing substrate 17 may be provided with, for example, a color filter and a light-shielding film as a black matrix (both unillustrated). Further, the sealing substrate 17 may be configured to absorb outside light reflected at a wiring line between the respective display devices 10 and to improve a contrast while extracting light generated in the display device 10. However, the display unit should secure transmissivity of an entire panel; it is preferable to achieve full colorization by emission colors such as RGB of the display unit (display device) itself instead of using the color filter. Also for the black matrix, the transmissivity of the entire panel should be secured as well; it is preferable to select the black matrix appropriately in terms of the overall configuration of the device.

The color filter may include a red filter, a green filter, and a blue filter (none are illustrated), and may be arranged in order. Each of the red filter, the green filter, and the blue filter may have a rectangular shape, for example, and may be formed without any gap therebetween. Each of the red filter, the green filter, and the blue filter may be made of a resin in which a pigment is mixed; selection of the pigment allows for adjustment of light-transmissivity in target wavelength ranges of red, green, or blue to be high, and of light-transmissivity in other wavelength ranges to be low.

The light-shielding film may be configured, for example, by a black resin film or a thin film filter. The black resin film in which a black colorant is mixed may have an optical density of 1 (one) or higher. The thin film filter may be obtained by utilizing interference of a thin film. Among those, the light-shielding film made of the black resin film may be preferable in terms of easy formation at inexpensive cost. The thin film filter may attenuate light, for example, by utilizing interference of one or more stacked layers of a thin film made of metal, a metal nitride, or a metal oxide. Specific examples of the thin film filter may include a thin film filter made of chromium (Cr) and chromium oxide (III) (Cr₂O₃) which are stacked alternately.

Here, the respective layers from the anode 12 to the cathode 14, which configure the display device 10 may be formed by a dry process such as the vacuum vapor deposition method, an ion beam method (IB method), a molecular beam epitaxy method (MBE method), a sputtering method, and an organic vapor phase deposition (OVPD) method.

Further, the organic layer 13 may also be formed by, in addition to the above-described methods, application methods such as a laser transfer method, the spin coating method, a dipping method, a doctor blade method, an ejection coating method, and a spray coating method; and wet processes including printing methods such as an inkjet printing method, an offset printing method, a letterpress printing method, an intaglio printing method, a screen printing method, and a microgravure coating method. The dry process and the wet process may also be used together depending on properties of the respective organic layers and the respective members.

In the display unit 1, a scanning signal is supplied from the scanning line drive circuit 130 to each of the pixels through the gate electrode of the write transistor Tr2, and an image signal may be supplied from the signal line drive circuit 120 through the write transistor Tr2 to a holding capacitor Cs and may be stored therein. In other words, the drive transistor Tr1 may be on/off controlled depending on the signal held in the holding capacitor Cs. This causes a drive current Id to be injected into the display device 10, and thus holes and electrons are recombined to cause light emission.

In each of the display devices (e.g., organic electroluminescence device) that configure the display unit, each of positive carriers (positive electric charges) and negative carriers (negative electric charges) may be injected into the organic layer from a pair of electrodes (anode and cathode) disposed to face each other. Movement of the electric charges in the organic layer and recombination of the positive electric charges and the negative electric charges in the light-emitting layer may cause an exciton in a singlet excited state (singlet exciton) to be generated; in the case of a fluorescent light-emitting device, when the singlet exciton undergoes energy relaxation to a ground state, a portion of the energy may become emission light.

As a method for improving the luminous efficiency (light extraction efficiency) of the display unit, it is contemplated that, for example, luminous efficiency inside the display device may be enhanced, or the emission region may be controlled. However, the primary issue may be that light emitted from the light-emitting layer is totally reflected in an in-plane direction due to refractive index difference at an interface between the substrate and the organic layer, causing photons extracted to the outside to be as low as about 20% of emitted photons.

The luminous efficiency is represented by the following expression (1):

Φext=γ×Φint×Φrev×Φout (1)

where Φext denotes external quantum yield, Φint denotes internal quantum yield, γ denotes balance factor, Φrev denotes probability of recombination of electric charges inside light-emitting layer, and Φout denotes yield of extracting emission light to outside.

That is, it is appreciated that, in order to improve the luminous efficiency, it may be sufficient to improve the four factors that constitute the external quantum yield (Φext). The internal quantum yield (Φint) is substantially determined by a fluorescent quantum yield of a luminescent material, and thus it is preferable to select a luminescent material having a fluorescent quantum yield close to 1 (one). The probability of recombination of charges inside the light-emitting layer (Φrev) is substantially determined by host/guest configuration of the light-emitting layer, although it depends on a layered structure of the organic layer. The probability of recombination of charges inside the light-emitting layer (Φrev) is a factor that may be improved in consideration of the overall device structure.

Further, it is also an effective measure to bring electron/hole injection balance factor γ close to 1 (one); improvement in carrier balance is requested. However, the injection balance factor γ is a consolidated representation of various factors that are difficult to be described in detail. Therefore, it is difficult to analyze what is the cause of effects obtained by the improvement in the carrier balance. Accordingly, it is difficult to positively discuss the electron/hole injection balance factor γ as a method for improving the luminous efficiency.

In contrast, the yield of extracting emission light to outside (Φout) is about 20%, and is about 30% at most, as described above. The refractive index of a low-molecular organic material used for a typical organic layer has in general a value of about 1.8 regardless of the molecular skeleton and the type thereof. Thus, there is a difference in the refractive index with respect to glass having a refractive index of 1.5, so that the emission light is totally reflected by a surface of the glass. In this manner, only about 30% at most of light (emission light) generated in the light-emitting layer is used for the display; the remaining emission light is propagated inside the device and is changed into heat to be deactivated. That is, it is appreciated that, by extracting light propagating inside the device to the outside, it becomes possible to largely enhance the luminous efficiency (light extraction efficiency) of the display unit.

In order to extract the light propagating inside to the outside, it is easy and convenient to use lens components such as a micro lens array or an optical prism as described above. However, there is expression of a diffraction pattern due to presence of a cycle pattern or a large influence on scattered light, which results in limited applicable range of electronic apparatuses.

Examples of the method for extracting the light propagating inside may include a method of using localized surface plasmon resonance, in addition to the addition of the above-mentioned components, for example.

The plasmon refers to a particle state in which free electrons in metal oscillate collectively to behave as pseudo-particles; for example, in a case of using a metal nanoparticle, the plasmon is locally present on the surface of the metal nanoparticle. The metal nanoparticle undergoes interaction between an optical electric field in a visible to near infrared region and the plasmon to cause light absorption, thus exhibiting a bright color hue. This phenomenon is referred to as the localized (local) surface plasmon resonance (LSPR), in which a remarkably intensified electric field is locally generated. This effect brings intensification of light emission such as acceleration of light emission of an illuminant near nano level and an increased path for light emission.

In order to improve the light extraction efficiency utilizing the surface plasmon resonance, it is important to understand plasmon dispersion relation for the use thereof. The wavenumber of the surface plasmon propagating an interface is represented as the following expression (2):

$${k}_{SP} ( ϖ ) \frac{ω}{c} \sqrt{\frac{{ɛ}_{metal}^{′} ( ω ) {ɛ}_{GaN}^{′} ( ω )}{{ɛ}_{metal}^{′} ( ω ) + {ɛ}_{GaN}^{′} ( ω )}} \qquad ( 2 )$$

where Kₛₚ(ω̅) denotes wavenumber of surface plasmon propagating interface, ω denotes number of oscillation, ∈′iGaN(ω) denotes dielectric function real part for GaN, ∈′metal(ω) denotes dielectric function real part for each metal, and ∈′GaN(ω)=∈′metal(ω).

Here, when using the metal nanoparticle, the surface plasmon oscillation (ωSP) and metal nanoparticles resonate to intensify the light emission. In other words, the wavenumber at which the dispersion curve at the interface diverges infinitely is unique for each metal; examples of the typical metal may include silver (Ag): 2.84 eV (437 nm), aluminum (Al): 5.50 eV (225 nm), and gold (Au): 2.46 eV (537 nm).

When the above-mentioned metal is provided near the light-emitting layer and the exciton energy is close to an energy of electron oscillation of the surface plasmon, both energies combine to form a path in which the surface plasmon is generated owing to energy transfer in addition to photons and phonons. However, the dispersion curve of the surface plasmon is in a non-radiation mode without overlapping light dispersion, and thus the surface plasmon results in having, as a main component, a component that attenuates as heat while propagating in an in-plane lateral direction.

That is, in order to obtain light emission intensification, it is requested that this surface plasmon be combined to photons again to cause light radiation. More specifically, providing a nano structure to an interface (or a vicinity thereof) between the metal layer (electrode) and the organic layer may cause the surface plasmon to have a modified wavenumber vector, which leads to loss of momentum and allows the wavenumber vector of the surface plasmon to intersect light dispersion line, thus enabling light to be amplified.

Therefore, in the display device 10 of the present embodiment, the electron transport layer 13D2 provided between the light-emitting layer 13C and the electrode (cathode 14 in this example) may be made of an organic material having microcrystallinity. This may form a nano structure near the interface between the metal (cathode 14) and the organic layer (organic layer 13), thus allowing the emission light to be amplified by an interaction (localized surface plasmon resonance) with respect to the cathode 14. Further, light emitted from the light-emitting layer 13C, in addition to the amplification of the emission light, may be scattered by the microcrystals that form the electron transport layer 13D2, thus allowing the light emitted from the light-emitting layer 13C to be collected in the light extraction direction.

As has been described above, according to the present embodiment, the electron transport layer 13D2 made of an organic material having microcrystallinity may be provided between the light-emitting layer 13C and the electrode (cathode 14 in this example.). This allows the light emitted from the light-emitting layer 13C to be amplified by the localized surface plasmon resonance and to be collected in the light extraction direction due to the scattering by the microcrystals, thus allowing for improvement in the efficiency of extracting light to the outside.

### 2. MODIFICATION EXAMPLE

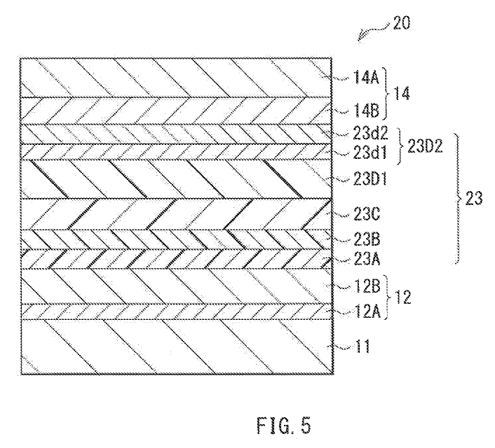

FIG. 5 illustrates a cross-sectional configuration of a display device 20 according to a modification example of the present disclosure. The display device 20 of the present modification example differs from the display device 10 of the present embodiment in that the electron transport layer 13D2 in the present embodiment is changed to a layered structure (electron transport layers 23D2: 23d1 and 23d2).

One or both of the electron transport layers 23D2 (23d1 and 23d2) may be made of an organic material having microcrystallinity similarly to the electron transport layer 13D2 in the foregoing embodiment. Examples of the material of the electron transport layer 23d1 and the electron transport layer 23d2 may include a triphenylene derivative, an azatriphenylene derivative, phthalocyanine derivative, an arylpyridine derivative or a benzimidazole derivative, a phenanthrene derivative, and a bathophenanthrene derivative. The electron transport layer 23d1 and the electron transport layer 23d2 may each have a layered structure configured by the same derivatives or derivatives having different mother skeletons.

In addition, the electron transport layer 23D2 having a layered structure may have a configuration in which, for example, the electron transport layer 23d1 on electron transport layer D1 side is made of an organic material having microcrystallinity, and the electron transport layer 23d2 in proximity to the cathode 14 is made of an organic material that form, with an electrode material, a chemical complex or an unsaturated pseudo-complex, thereby enabling the electron transport layer 23D2 having a layered structure to secure stability of the interface with respect to the cathode 14.

In order to improve the light extraction efficiency by using the microcrystalline organic material, it is important to effectively use the localized surface plasmon resonance (LSPR) effect. Therefore, for a material that forms the electron transport layer 23d2, it is preferable that there may be a close distance from the microcrystalline structure to specific metal that is important for generation of the plasmon. Thus, it is desirable to use an electron-transporting organic microcrystalline material having both a large electron-transporting property and a property excellent also in electron injection from a metal electrode.

### 3. APPLICATION EXAMPLE

Now, application examples of the display unit including any of the display devices 10 and 20 described in the foregoing embodiment and modification example are described below. The display unit of the foregoing embodiment is applicable to display units of electronic apparatuses in any fields that display, as an image or a picture, an image signal input from outside or an image signal generated inside, such as televisions, digital cameras, notebook personal computers, portable terminal devices such as mobile phones, and video cameras.

### (Module)

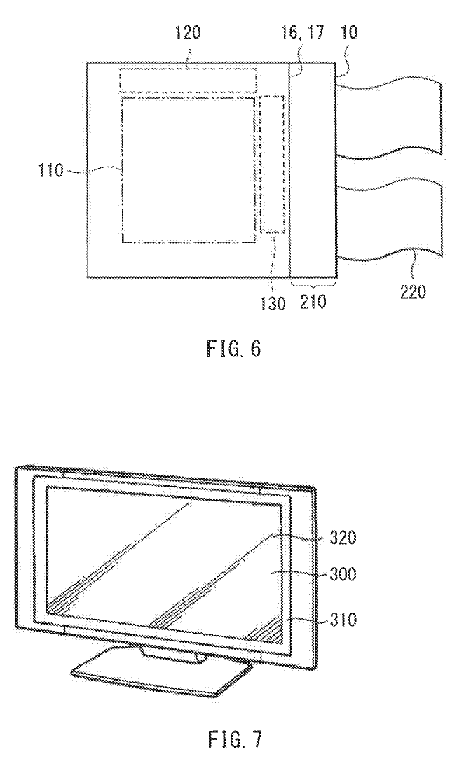

The display unit including any of the display devices 10 and 20 described in the foregoing embodiment and modification example may be incorporated, for example, as a module as illustrated in FIG. 6, into various electronic apparatuses such as those in Application Examples 1 to 5 described later. The module may have a configuration in which, for example, a region 210 that is exposed from the protective layer 16 and the sealing substrate 17 is provided at one side of the substrate 11, and wiring lines of each of the signal line drive circuit 120 and the scanning line drive circuit 130 are extended to the exposed region 210 to form an unillustrated external connection terminal. The external connection terminal may be provided with a flexible printed circuit (FPC) 220 for input/output of signals.

### Application Example 1

FIG. 7 illustrates an outer appearance of a television to which the display unit including any of the display devices 10 and 20 of the foregoing embodiment and modification example is applicable. The television may include, for example, an image display screen section 300 that includes a front panel 310 and filter glass 320. The image display screen section 300 may be configured by the display unit according to the foregoing embodiment and modification example.

### Application Example 2

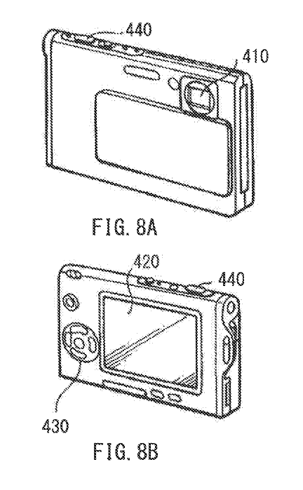

FIGS. 8A and 8B illustrate outer appearances of front side (FIG. 8A) and rear side (FIG. 8B) of a digital camera to which the display unit including any of the display devices 10 and 20 of the foregoing embodiment and modification example is applicable. The digital camera may include, for example, a flashlight-emitting section 410, a display section 420, a menu switch 430, and a shutter button 440. The display section 420 may be configured by the display unit according to the foregoing embodiment and modification example.

### Application Example 3

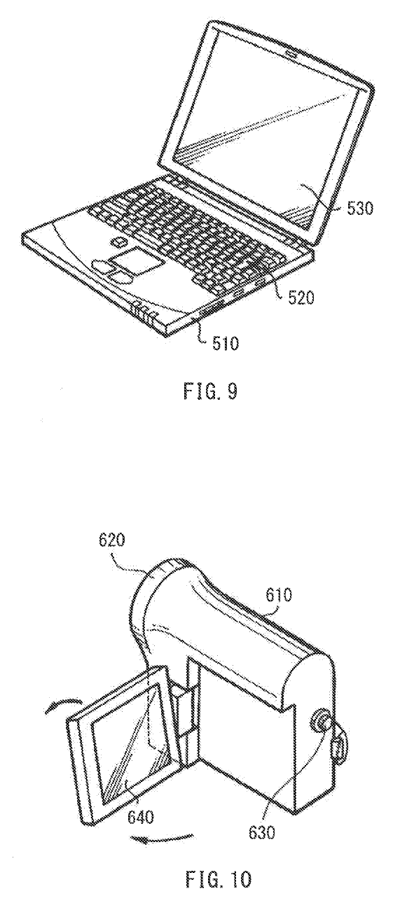

FIG. 9 illustrates an outer appearance of a notebook personal computer to which the display unit including any of the display devices 10 and 20 of the foregoing embodiment and modification example is applicable. The notebook personal computer may include, for example, a main body 510, a keyboard 520 for operation of inputting characters, for example, and a display section 530 for displaying an image. The display section 530 may be configured by the display unit according to the foregoing embodiment and modification example.

### Application Example 4

FIG. 10 illustrates an outer appearance of a video camera to which the display unit including any of the display devices 10 and 20 of the foregoing embodiment and modification example is applicable. The video camera may include, for example, a main body 610, a subject-shooting lens 620 provided on a front side surface of the main body 610, a shooting start/stop switch 630, and a display section 640. The display section 640 may be configured by the display unit according to the foregoing embodiment and modification example.

### Application Example 5

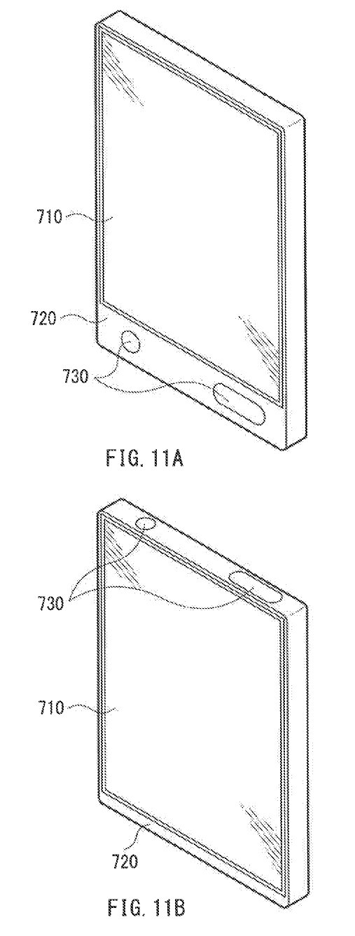

FIGS. 11A and 11B, respectively, illustrate front side and rear side of an outer appearance of a tablet computer to which the display unit including any of the display devices 10 and 20 of the foregoing embodiment and modification example is applicable. The tablet computer may include, for example, a display section 710 (display section 1), a non-display section (casing) 720, and an operation section 730. The operation section 730 either may be provided on the front surface of the non-display section 720 as illustrated in FIG. 11A, or may be provided on the top surface thereof as illustrated in FIG. 11B.

### 4. EXAMPLES

Next, examples (Examples 1 to 5) and comparative examples (Comparative Examples 1 to 3) of the present disclosure are described. Examples 1 to 5 described below correspond to the present embodiment and the present modification.

### Examples 1 to 5 and Comparative Examples 1 to 3

First, as the anode 12, the first layer 12 A made of chromium (Cr) (film thickness: 100 nm) and the second layer 12B made of indium oxide (IXO: available from Idemitsu Kosan Co., Ltd., located in Tokyo, Japan) (film thickness: 200 nm) were formed on the substrate 11 made of a glass plate of 30 mm×30 mm. Thereafter, silicon oxide (SiO₂) vapor deposition was used to prepare a cell for a display device, with a region other than an emission region of 2 mm×2 mm being masked with an unillustrated insulating film.

Next, the organic layer 13 was formed. First, the vacuum vapor deposition method was used to form, as the hole injection layer 13A, 2-TNATA[4,4′,4″-tris(2-naphthylphenylamino)triphenylamine] represented by the formula (1) at a vapor deposition rate of 0.2 to 0.4 nm/sec. both inclusive and at a film thickness of 15 nm. Thereafter, as the hole transport layer 13B, α-NPD(α-naphthyl phenyl diamine) represented by the formula (2) was formed at a vapor deposition rate of 0.2 to 0.4 nm/sec. both inclusive and at a film thickness of 15 nm. Thereafter, BD-052x (available from Idemitsu Kosan Co., Ltd., located in Tokyo, Japan) as a dopant material was applied to 9,10-di(2-naphthyl)anthracene (ADN) represented by the formula (3) as a host material of the light-emitting layer 13C to form a film having a total film thickness of 30 nm. Next, as the electron transport layer 13D1, 8-hydroxyquinoline aluminum (Alq3) represented by the formula (4) was subjected to vapor deposition at a film thickness of 18 nm.

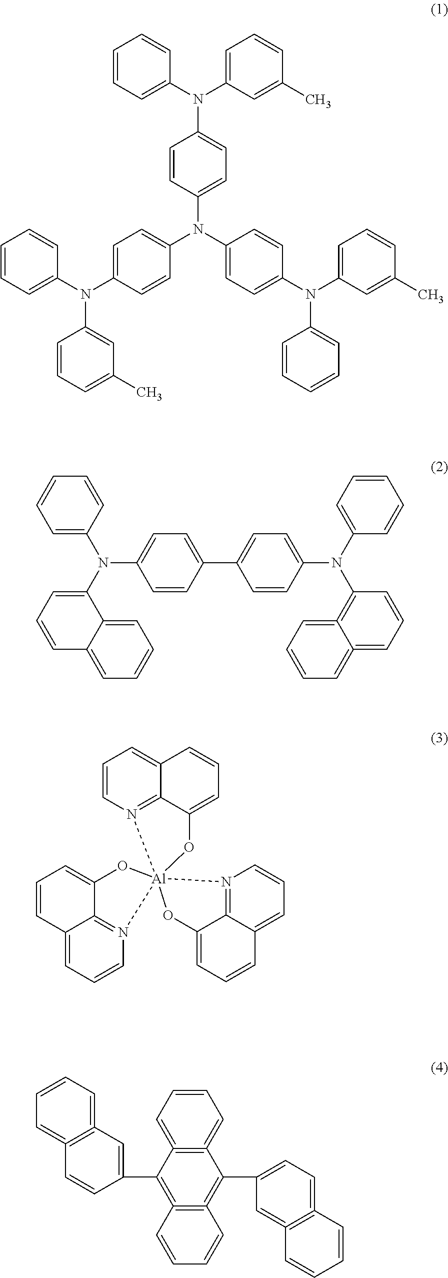

Thereafter, as the electron transport layer 13D2, a microcrystalline electron transport material (compound A, B, C, D, E, F or G) was formed by vacuum vapor deposition at a film thickness of 15 nm on the electron transport layer 13D1.

Next, as the first layer 14A of the cathode 14, lithium fluoride (LiF) was formed by the vacuum vapor deposition method at a vapor deposition rate of 0.01 nm/sec. and at a film thickness of about 0.3 nm, following which, as the second layer 14B, a magnesium-silver alloy (MgAg) was formed by the vacuum vapor deposition method at a film thickness of 10 nm to prepare top emission display devices (Examples 1 to 5, and Comparative Examples 1 and 3).

Lastly, silicon nitride oxide (SiNₓO_{y}) as the protective layer 16 was formed on the cathode 14 at a film thickness of 2 μm by a plasma chemical vapor deposition (CVD) method, following which the sealing substrate 17 was joined to the formed protective layer 16 using a transparent thermosetting resin.

It is to be noted that Comparison Example 2 is directed to a display device prepared by forming the electron transport layer with a common electron transport material (Alq3), instead of the microcrystalline electron transport material, for the organic layer (e.g., electron transport layer) at a film thickness of 15 nm under optical conditions in accordance with those in Examples 1 to 5 and Comparative Examples 1 and 3.

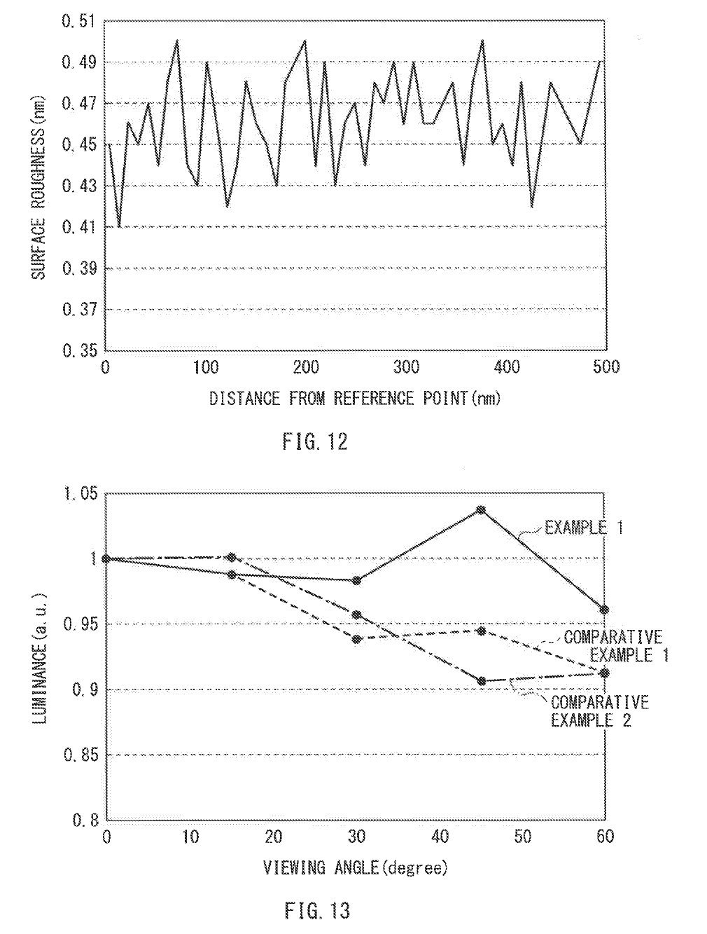

Luminous efficiency (cd/A) and luminance half-life (h) of the display devices of Examples 1 to 5 and Comparative Examples 1 to 3 prepared as described above were measured at a current density of 10 nAcm⁻². Further, a surface property (surface roughness) of a single film was measured using an atomic force microscope (AFM). Table 1 summarizes evaluations of crystalline states and average surface roughness of the electron transport layers of Examples 1 to 5 and Comparative Examples 1 to 3 as well as device characteristics (drive voltage, dependency of luminance on viewing angle, and driving life) of Examples 1 to 5 and Comparative Examples 1 and 3 with reference to Comparative Example 2. In this table, A indicates remarkable improvement; B indicates a certain degree of improvement; C indicates the same degree as Comparative Example 2; and D indicates deterioration compared to Comparative Example 2. It is to be noted that FIG. 12 illustrates measurement results of surface roughness in a distance from the reference point in Example 4, and FIG. 13 illustrates dependency of luminance on viewing angle in Example 1 and Comparative Examples 1 and 2. The average surface roughness (nm) shown in Table 1 is an average value of roughness measured at points by 10 nm from the reference point within a range of 100 nm×100 nm (at 121 measuring points of 11×11).

TABLE 1

| | | | | | | Comparative | Comparative | Comparative |
|---|---|---|---|---|---|---|---|---|
| | Example 1 | Example 2 | Example 3 | Example 4 | Example 5 | Example 1 | Example 2 | Example 3 |
| Microcrystalline | Compound | Compound B | Compound D | Compound E | Compound F | Compound C | — | Compound G |
| Electron | A | | | | | | | |
| Transport | | | | | | | | |
| Material | | | | | | | | |
| Drive Voltage | A | A | A | A | A | D | — | B |
| Dependency of | A | A | A | A | A | C | — | B |
| Luminance on | | | | | | | | |
| Viewing Angle | | | | | | | | |
| Driving Life | A | C | C | A | A | D | — | C |
| Average | 27.6 | 0.23 | 9.32 | 0.46 | 0.93 | 0.31 | 0.1 | 0.27 |
| Surface | | | | | | | | |
| Roughness | | | | | | | | |
| (nm) | | | | | | | | |
| Crystalline State | Needle | Needle | Flat Plate | Particulate | Particulate | Particulate | — | Particulate |
| | Crystal; | Crystal; | Stack; | | | | | |
| | In-Plane | In-Plane | Grain | Crystal; | Crystal; | Crystal; | | Crystal; |
| | Horizontal; | Vertical and | Formation; | | | | | |
| | Random | In-Plane | In-Plane | Random | Random | Random | | Random |
| | | Horizontal | Vertical | | | | | |
| | | Present | | | | | | |
| | | Together | | | | | | |

It is appreciated from Table 1 and FIG. 13 that, in Examples 1 to 4 provided with the electron transport layer 13D2 using the microcrystalline electron transport material, the dependency of luminance on viewing angle was improved compared to Comparative Example 2, with Example 1, in particular, having the highest improvement rate. That is, it is appreciated that, in order to improve the dependency of luminance on viewing angle, it is most preferable to provide a needle crystal between the electrode (e.g., cathode 14) and the light-emitting layer 13C as well as a layer (e.g., electron transport layer 13D2) dispersed randomly in an in-plane horizontal direction. This improves not only front luminance but also luminance at a high viewing angle, thus enhancing the light extraction efficiency. Further, in Example 1, the drive voltage was reduced, and the driving life was also enhanced, in addition to the enhancement of the light extraction efficiency.

It is to be noted that an in-plane vertical needle crystal may be present together inside the electron transport layer 13D2. In addition, the electron transport layer 13D2 may be configured by a disk-shaped crystal, or a particulate crystal, as long as the particulate crystal is formed such that the surface property of the electron transport layer 13D2 has a predetermined average surface roughness, more specifically, an average surface roughness that is integer times as or an integer fraction of a peak wavelength of light to be desired to be extracted. The disk-shaped crystal forms a grain structure inside the electron transport layer 13D2. Further, in the case of the electron transport layer 13D2 being configured by the microcrystalline crystal (Comparative Example 1), increase in the drive voltage and decrease in the driving life were confirmed. It is to be noted that the light to be desired to be extracted refers to light emitted from the light-emitting layer 13C. Further, the peak wavelength of light to be desired to be extracted refers to, for example, a peak wavelength of an internal spectrum in the light-emitting layer estimated from the device structure and the results of an emission spectrum. When the peak wavelength and the average surface roughness have a close value (e.g., integer times or an integer fraction), the extraction efficiency is improved.

Although description has been given of the disclosure referring to the embodiment and the modification example, the disclosure is by no means limited to the foregoing embodiment and modification example, and various modifications are possible.

For example, although description has been given of the case of the active matrix display unit using a thin film transistor (TFT) substrate in the foregoing embodiment and modification example, this is not limitative; a passive matrix display unit may also be adopted. Further, the configuration of the pixel drive circuit that performs active matrix drive is not limited to those described in the foregoing embodiment; a capacitor or a transistor may be added as necessary. In this case, a necessary drive circuit may be added, in addition to the above-described signal line drive circuit 120 and the scanning line drive circuit 130, depending on alteration of the pixel drive circuit.

Furthermore, although description has been given of the case of the top emission display device in which light is extracted from the cathode 14 side provided on side opposite to the substrate 11 in the foregoing embodiment and modification example, the disclosure is also applicable to a bottom emission display device with the substrate 11 being configured by a transparent material. In this case, the bottom emission display device may have either a configuration in which the layered structure of the display device 10 illustrated in FIG. 1 is inverted from the substrate 11 side, or a configuration in which the same structure is formed on a transparent electrode that is provided on a transparent substrate. There is a concern that a layer made of the microcrystalline organic material (microcrystalline organic material layer) has a tendency to have increased roughness of a layer surface compared to a layer made of an amorphous material, thus making short-circuit between electrodes likely to occur. Thus, it is preferable to form the microcrystalline organic material layer on upper layer side of the layered structure; however, this is not the case when the microcrystalline organic material layer is a thin film or when a material to be stacked has a high coverage property. Moreover, forming the cathode 14 that serves as the upper electrode with a transparent material makes it possible to extract light both from the substrate 11 and from side opposite to the substrate 11.

Furthermore, the description has been given with reference specifically to the configurations of the display devices 10 and 20 in the foregoing embodiment and modification examples; however, all the layers are not necessarily provided, and another layer may also be provided. For example, the light-emitting layer 13C may be provided directly on the hole injection layer 13A without providing the hole transport layer 13B thereon. Alternatively, a layer having an electron injection property (electron injection layer) may be provided between the electron transport layer 13D and the cathode 14.

It is to be noted that the effects described herein are mere examples. The effect of the technology is not limited thereto, and may include other effects.

It is to be noted that the technology may also have the following configurations.

(1)

A display device including:

a first electrode;

a second electrode;

a light-emitting layer included in an organic layer, the organic layer being provided between the first electrode and the second electrode; and

an organic material layer provided between the first electrode and the light-emitting layer, and having microcrystallinity.

(2)

The display device according to (1), wherein the organic material layer contains a needle crystal.

(3)

The display device according to (1) or (2), wherein the needle crystal has a crystal length of one μm or less.

(4)

The display device according to (1), wherein the organic material layer contains a disk-shaped crystal.

(5)

The display device according to (1), wherein the organic material layer contains a particulate crystal.

(6)

The display device according to (5), wherein the particulate crystal has an average surface roughness of 0.5 nm or less.

(7)

The display device according to any one of (1) to (6), wherein the organic material layer has an average surface roughness that is integer times as or an integer fraction of a peak wavelength of light to be emitted from the light-emitting layer.

(8)

The display device according to any one of (1) to (7), wherein the organic material layer is made of an organic material having single microcrystallinity.

(9)

The display device according to any one of (1) to (8), wherein the organic material layer is made of an electron-transporting material.

(10)

A display unit including a plurality of display devices, the display devices each including:

a first electrode;

a second electrode;

a light-emitting layer included in an organic layer, the organic layer being provided between the first electrode and the second electrode; and

an organic material layer provided between the first electrode and the light-emitting layer, and having microcrystallinity.

(11)

An electronic apparatus provided with a display unit, the display unit being provided with a plurality of display devices in a display section, the display devices each including:

a first electrode;

a second electrode;

a light-emitting layer included in an organic layer, the organic layer being provided between the first electrode and the second electrode; and

an organic material layer provided between the first electrode and the light-emitting layer, and having microcrystallinity.

According to the display device, the display unit including the display device, and the electronic apparatus of an embodiment of the technology, provision of the organic material layer having microcrystallinity between the light-emitting layer and the first electrode may allow light emitted from the light-emitting layer to be scattered, or to be amplified by an interaction with the first electrode.

According to the display device, the display unit including the display device, and the electronic apparatus of an embodiment of the technology, the organic material layer having microcrystallinity may be provided between the light-emitting layer and the first electrode. This may allow light emitted from the light-emitting layer to be scattered, to thereby cause the light to be collected in a light extraction direction. Alternatively, the light may be amplified by the interaction with the first electrode. This makes it possible to improve the efficiency of extracting light to the outside. It is to be noted that the effects described herein are not necessarily limitative, and may be any of the effects described in the disclosure.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably” or the like is non-exclusive and means “preferably”, but not limited to. The use of the terms first, second, etc. do not denote any order or importance, but rather the terms first, second, etc. are used to distinguish one element from another. The term “about” as used herein can allow for a degree of variability in a value or range. Moreover, no element or component in this disclosure is intended to be dedicated to the public regardless of whether the element or component is explicitly recited in the following claims.

What is claimed is:

1. A display device comprising:
a first electrode;
a second electrode;
a light-emitting layer included in an organic layer, the organic layer being provided between the first electrode and the second electrode; and
an organic material layer provided between the first electrode and the light-emitting layer, and having microcrystallinity.

2. The display device according to claim 1, wherein the organic material layer contains a needle crystal.

3. The display device according to claim 2, wherein the needle crystal has a crystal length of one μm or less.

4. The display device according to claim 1, wherein the organic material layer contains a disk-shaped crystal.

5. The display device according to claim 1, wherein the organic material layer contains a particulate crystal.

6. The display device according to claim 5, wherein the particulate crystal has an average surface roughness of 0.5 nm or less.

7. The display device according to claim 1, wherein the organic material layer has an average surface roughness that is integer times as or an integer fraction of a peak wavelength of light to be emitted from the light-emitting layer.

8. The display device according to claim 1, wherein the organic material layer is made of an organic material having single microcrystallinity.

9. The display device according to claim 1, wherein the organic material layer is made of an electron-transporting material.

10. A display unit including a plurality of display devices, the display devices each comprising:
a first electrode;
a second electrode;
a light-emitting layer included in an organic layer, the organic layer being provided between the first electrode and the second electrode; and
an organic material layer provided between the first electrode and the light-emitting layer, and having microcrystallinity.

11. An electronic apparatus provided with a display unit, the display unit being provided with a plurality of display devices in a display section, the display devices each comprising:
a first electrode;
a second electrode;
a light-emitting layer included in an organic layer, the organic layer being provided between the first electrode and the second electrode; and
an organic material layer provided between the first electrode and the light-emitting layer, and having microcrystallinity.
